(19) United States
(12) Patent Application Publication
(10) Pub. No.: US 2013/0284226 A1
(43) Pub. Date: Oct. 31, 2013

(54) Thermoelectric Converter with Improved Heat Transfer Medium

(71) Applicant: Thilo Ittner, (US)

(72) Inventor: Thilo Ittner, Ravensburg (DE)

(21) Appl. No.: 13/868,417

(22) Filed: Apr. 23, 2013

(30) Foreign Application Priority Data
Apr. 26, 2012 (EP) 12165774.6

(51) Int. Cl. H01L 35/28

(52) U.S. Cl. CPC H01L 35/28
USPC 136/201; 136/200

(57) ABSTRACT

A thermoelectric converter for converting quantities of heat into electric energy or electric energy into quantities of heat, or quantities of heat of certain temperatures into quantities of heat of certain other temperatures, includes at least two primary volumes connected to each other by at least one connecting element. Each primary volume includes one gas volume that is suited for receiving gas. One or both of the primary volumes include a liquid volume suited for receiving a liquid. The liquid can be coupled thermally to an external heat reservoir, an external source of heat, or an external heat sink. At least one volume-changing element is provided in at least one of the primary volumes for changing the size of the gas volume. A heat transfer element is provided in at least one of the primary volumes, wherein the proportion of the heat transfer element located in the liquid volume is variable.

The present disclosure relates to a thermoelectric converter with an improved heat transfer medium for exchanging heat with a process gas.

### BACKGROUND

In prior art, different devices for converting quantities of heat into electric energy, or electric energy into quantities of heat are already known. These find application in many fields and usually contain pistons or membranes for changing the volume of an employed process gas. These volume-changing elements can be driven either mechanically, for example by crankshafts, or electromagnetically, as is described in EP 2258947 A1. Furthermore, these machines typically have several working spaces between which the temperature of the employed process gas changes, thereby causing a change of pressure. For machines which in particular utilize regenerative gas cycles, it is furthermore known to employ a regenerator provided between the working spaces. This regenerator stores the emitted heat of the gas that flows through it and emits it again to the latter when it is flowing back.

In present prior art, however, several technical problems occur in the realized cycle due to which an efficiency that is only considerably lower than the theoretically possible efficiency of a Carnot cycle can be achieved. These problems are in particular the occurrence of dead volumes which are volume fractions from which the process gas cannot be removed during the cycle. These are mainly the regions of the heat exchangers and the regenerators. One of the severest problems is the fact that due to the finite speed of heat transfer within the process gas, it is not possible to perform changes of state actually isothermally because the heat exchanger can only heat gas within a certain area around it.

### SUMMARY

It is an object of some aspects of the present disclosure to provide a thermoelectric converter with an improved heat transfer medium.

This object, in some arrangements, may be achieved by the device according to claim 1 and the method according to claim 9. Advantageous embodiments of the disclosure are referred to in the dependent claims.

In some arrangements, the thermoelectric converter for converting quantities of heat into electric energy, or electric energy into quantities of heat, or quantities of heat of certain temperatures into quantities of heat of certain other temperatures, includes at least two primary volumes which are connected to each other and each comprise a gas volume suited for receiving a gas, and wherein at least one of the primary volumes or both comprise a liquid volume suited for receiving a liquid, wherein the liquid can be thermally coupled to a heat reservoir (an external source of heat or a heat sink), and wherein at least one volume-changing element is provided in at least one of the primary volumes for changing the size of the gas volume, is characterized in that a heat transfer element is furthermore provided in at least one of the primary volumes, and the proportion of the heat transfer element located in the liquid volume is variable. If a liquid is located in the liquid volume which can be thermally coupled to an external heat reservoir, the heat transfer element permits an effective heat exchange between the gas and the liquid by immersing it into the liquid volume to different extents. This is ensured by the heat transfer element being positioned in one setting preferably completely outside the liquid and exchanging heat with the gas, and in a further setting being preferably completely immersed in the liquid to exchange heat with the latter.

With the heat transfer element, heat can be transferred from the liquid to the gas (the liquid heats the gas), or heat can be transferred from the gas to the liquid (the gas heats the liquid), depending on the construction or operation of the converter. The connection of the two primary volumes preferably may include a regenerator.

In one embodiment, the device is characterized in that the heat transfer element comprises an area which is larger than the area of the surfaces defining the gas volume (preferably twice as large, preferably 5 times as large). Such a large area permits to achieve a preferably effective exchange of heat between the gas and the heat transfer element on the one side, and the heat transfer element and the liquid on the other side, and thus between the gas and the liquid. This permits a nearly isothermal process control due to the heat exchange between the gas and the heat transfer element taking place uniformly in a large portion of the gas volume.

In another embodiment, the device is characterized in that the heat transfer element is either fixed to the surface of the volume-changing element facing the liquid volume, or is firmly provided at the surfaces defining the primary volume. By mounting the heat transfer element to the movable solid (neither liquid nor gaseous) volume-changing element, an additional movable mounting of the heat transfer element can be avoided, and one simultaneously achieves that the gas moved by the volume-changing element is always heated by the heat transfer element. If the heat transfer element is firmly fixed to the surfaces defining the primary volume, more flexible embodiments of the volume-changing element result.

In another embodiment, the device is characterized in that the heat transfer element comprises either a plurality of separate plates, a plurality of separate rods, a plurality of grids connected to each other, or a metallic foam permeable to liquid and gases. These plates, rods, the grid, or the metallic foam have spaces which have maximal dimensions of <20 mm, preferably <10 mm, preferably <2 mm, in at least one direction. The advantage of this is that a good heat exchange between the liquid and the heat transfer element or between the gas and the heat transfer element is permitted. Combinations of these possibilities are also conceivable in this embodiment. Preferably, the plates, the rods and the grid consist of a material that is a good heat conductor, for example metals, the thermal conductivity of the material being at least

$$λ \geq 10 \frac{W}{m \cdot K} .$$

By this embodiment of the heat transfer element, the heat transfer element can ensure a preferably complete heat exchange when it is immersed into the liquid. This is achieved in that a major portion (at least 60%, preferably 80%, preferably 90%) or the complete material forming the heat transfer element exchanges heat with the liquid. Furthermore, this embodiment of the heat transfer element permits a preferably large area for heat exchange available for the gas.

In another embodiment, the device is characterized in that electromagnetic components are provided which are suited for a movement of the volume-changing element. Thereby, one can achieve movements of the volume-changing element which can deviate from the movement according to harmonic oscillation as employed in well-known mechanical pistons. In particular, movements of a defined amplitude can be achieved thereby which is, unlike in harmonic oscillation, independent of the speed of the volume-changing element when it passes the center of motion.

In one embodiment, the device is characterized in that the volume-changing element comprises either a movable piston, a rotary piston, a movable membrane, a movable regenerator, or the liquid itself. The embodiment of the volume-changing element with the aid of a solid body permits the direct connection of the volume-changing element with devices for carrying out the movement of the volume-changing element, and a connection of the volume-changing element with the heat transfer element, whereby additional motors and movable components can be eliminated. The design of the volume-changing element by means of the provided liquid permits a change of volume of the process gas just by lifting and lowering the liquid level, whereby a very uniform and impact-free change of volume is given, and it furthermore permits to fix the heat transfer element to the limiting surfaces forming the primary volume.

In another embodiment, the device is characterized in that at least at one volume-changing element, or at the surfaces defining the primary volume, a possibly movable absorber is provided which can convert electromagnetic radiation into heat and transfer it to the process gas. Thereby, sunlight can preferably be provided for heating the process gas, and thus solar energy can be utilized for performing volume work and achieving heat exchange with a liquid.

In another embodiment, the device is characterized in that it is provided either as an alpha Stirling machine, a duplex-alpha Stirling machine, a multiple-acting alpha Stirling machine, a beta/gamma Stirling machine, a duplex-beta/gamma Stirling machine, a multiple acting beta/gamma Stirling machine, or as a Vuilleumier cycle machine. The design of the devices in one of these possible embodiments permits a flexible use in most diverse working fields. Duplex Stirling machines are machines that have two pairs of gas volumes of variable sizes connected to regenerators. Multiple-acting Stirling machines are machines that have more than two pairs of gas volumes of variable sizes connected to regenerators. Duplex or multiple-acting Stirling machines in particular offer the possibility of combining clockwise and anticlockwise Stirling processes and, among other things, of thus converting quantities of heat of certain temperatures into quantities of heat of certain other temperatures.

In another embodiment, the device is characterized in that the volume-changing element comprises a rotary piston which either contains a gas-permeable regenerator or is impermeable to gas, and which can change the volume of two different gas volumes by its periodic rotary motion with changing senses of rotation.

Using this device, for example, a method for converting quantities of heat into electric energy, or electric energy into quantities of heat, or quantities of heat of certain temperatures into quantities of heat of certain other temperatures, can be realized by means of a thermoelectric converter, the method being characterized in that the proportion of a heat transfer element located in the liquid volume changes periodically. By this method, effective heat exchange can be realized between the process gas and the heat transfer element on the one side, and the heat transfer element and the liquid on the other side.

In one embodiment, the method is characterized in that a liquid is permanently located in the liquid volume. Since devices for thermally coupling the liquid in the liquid volume are provided, one can thus dispense with devices for discharging the liquid from the liquid volume. As an alternative, one can dispense with devices for thermal coupling within the primary volumes, and a discharge of the liquid can be achieved, for example, by circulation or pumping, and outside the primary volumes, a heat exchange with, for example, a coolant circuit can take place, or the liquid itself can belong to a coolant circuit, for example of an internal combustion engine.

In one embodiment, the method is characterized in that the volume-changing element is periodically moved or deformed by electromagnetic components. This permits, in contrast to common mechanical couplings of the volume-changing element, the movement of the volume-changing element according to a non-harmonic movement.

In one embodiment, the method is characterized in that the amplitude of the movement of the volume-changing element is controlled such that the speed of the volume-changing element, when it passes the center of motion, is higher than the speed of a harmonic oscillation of the same period. Preferably, the speed is by 10% or 20% higher than that of harmonic oscillation.

In another embodiment, the method is characterized in that the volume-changing elements are moved within the primary volumes such that during a compression phase, a multiple (at least four, preferably at least eight, preferably at least 20 times) of the process gas of the first primary volume is located in the second primary volume, and during an expansion phase, a fraction (preferably ⅓, preferably ⅛, preferably 1/10) of the process gas of the first primary volume is located in the second primary volume. One achieves thereby that nearly the complete process gas is located in the suited working range, and thus a preferably isothermal process control is realized and dead volumes are minimized.

In one embodiment, the method is characterized in that the heat transfer elements can be moved relative to the limiting surfaces forming the primary volume. Preferably, the heat transfer elements are here firmly connected with the volume-changing elements, whereby one can dispense with additional drive elements for the heat transfer elements.

In one embodiment, the method is characterized in that the volume change of the gas volume is performed by changing the proportion of the liquid volume in the primary volume. In this case, the liquid functions both as medium for heat exchange with the gas by means of the heat transfer elements, and simultaneously as volume-changing element, and it thus renders the installation of further mechanical parts in the primary volume outside the liquid volume avoidable, thus permitting a larger primary volume.

### BRIEF DESCRIPTION OF THE FIGURES

FIG. 1 is a schematic representation of a device according to the invention as an alpha Stirling machine.

FIGS. 2A-D are schematic representations of a complete cycle of a device according to the invention.

FIG. 3 is a schematic representation of a device according to the invention in an embodiment with a movable liquid column as a volume-changing element.

FIG. 4 is a schematic representation of a device according to the invention in an embodiment as a duplex-alpha machine.

FIG. 5 is a schematic representation of a device according to the invention in an embodiment as a duplex-gamma Stirling machine.

FIG. 6 is a schematic representation of a device according to the invention in an embodiment with a rotary piston.

### DETAILED DESCRIPTION OF THE FIGURES

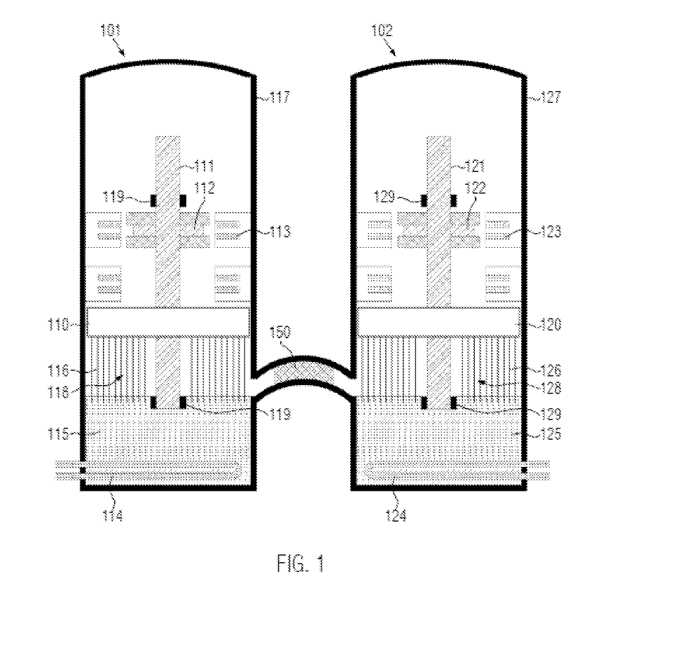

FIG. 1 shows an embodiment of a device according to the disclosure as an alpha Stirling machine. The latter comprises two cylinders 101 and 102 which each form the primary volume 117 and 127, respectively. A connection of these two primary volumes 117 and 127 is realized via the connecting element 150 with the regenerator. In the primary volumes, liquid volumes 115 and 125 and gas volumes 118 and 128, respectively, are provided. Preferably, liquid is permanently present in the liquid volumes 115 and 125. Furthermore, a volume-changing element 110 is provided in a first primary volume 117, and a further volume-changing element 120 is preferably provided in the second primary volume 127. Heat transfer elements 116 and 126 are provided at each of these volume-changing elements, the heat transfer elements preferably consisting of metal, while they in particular have a very large surface area and high thermal conductivity. The volume-changing elements (for example pistons) 110 and 120 are furthermore connected, for example, to a piston rod 111 and 121, respectively. Preferably, permanent magnets 112 and 122 are located at this piston rod, which is moreover guided by gas or sliding or hydrodynamic bearings 119 and 129, respectively. As an alternative to these bearings, a mounting of the pistons could also be realized by means of deformable elements, such as spring bands or cup springs. Furthermore, coils 113 and 123 are provided at the surfaces defining the primary volumes 117 and 127, respectively. By the interaction of the permanent magnet 112 and the coils 113, a movement of the volume-changing element 110 is caused or controlled by open-loop or closed-loop control. As can be seen in the picture, the latter can be moved at least perpendicularly to the limiting surface between the gas volume 118 and 128 and the liquid volume 115 and 125, respectively, perpendicularly to the surface of the liquid. The mechanisms required for the movement do not have to be designed electromagnetically, they can rather also be realized via mechanical connections. By the movement of the volume-changing elements 110 and 120, the proportion of the heat transfer elements 116 and 126 located within the liquid volume 115 and 125, respectively, is varied. Since heat exchangers 114 and 124 are provided in the liquid volumes 115 and 125 for thermally coupling the liquid contained each in the liquid volumes 115 and 125 with preferably external heat reservoirs, sources of heat or heat sinks, the variation of the proportion of the heat transfer elements 116 and 126, which are located in the liquid volumes 115 and 125 and thus in thermal contact with the corresponding liquids, will lead to a heat exchange between the liquids and the heat transfer elements 116 and 126. Furthermore, by the movement of the heat transfer elements and the volume-changing elements 110 and 120, a heat exchange between the heat transfer elements 116 and 126 with the gas located in the gas volumes 118 and 128 occurs. If the movement of the volume-changing elements 110 and 120 in the cylinders 101 and 102 is suitably controlled, for example by a control unit, with different temperatures of the liquids in the liquid volumes 115 and 125, a thermodynamic cycle can be realized.

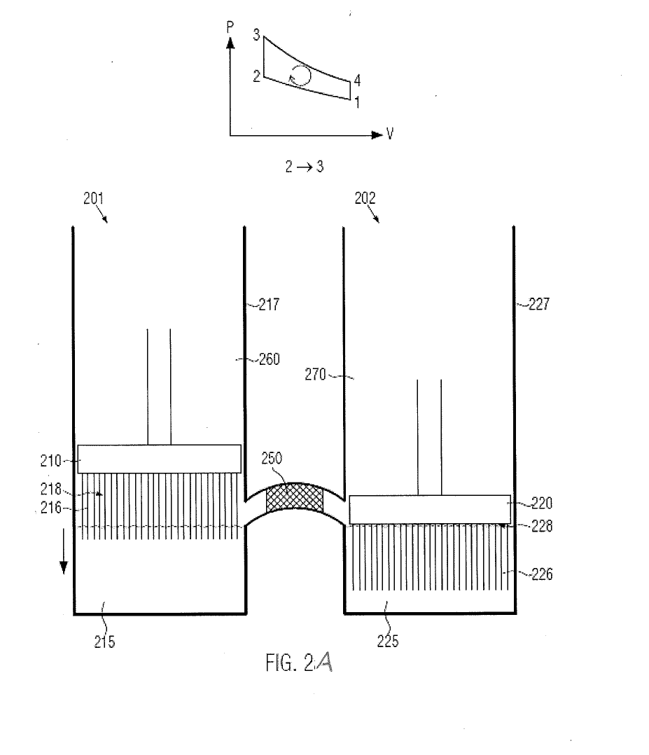

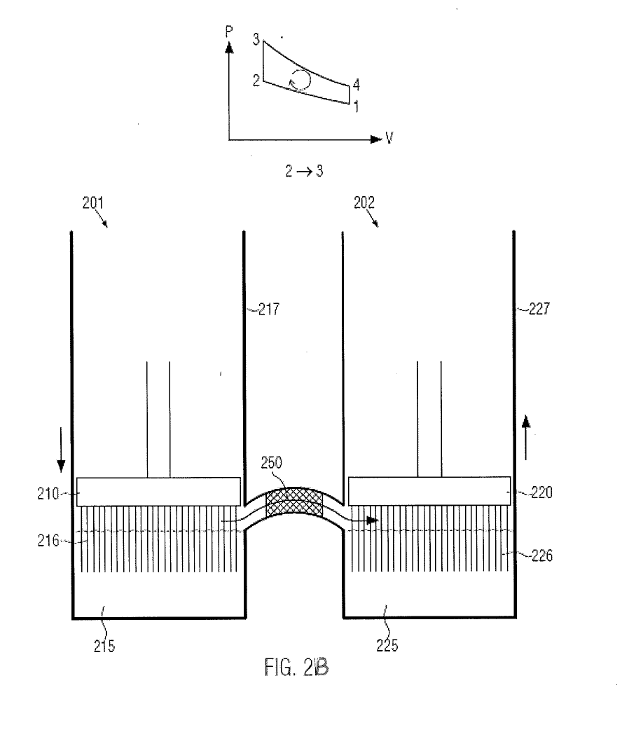

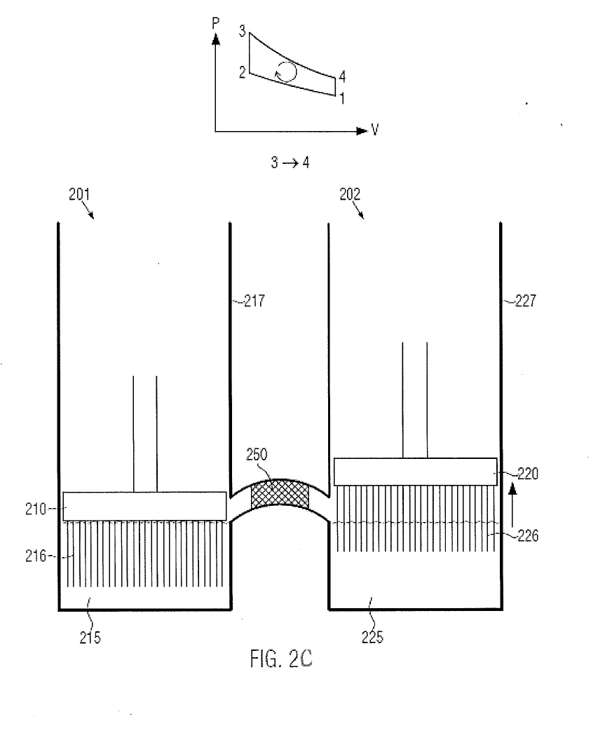

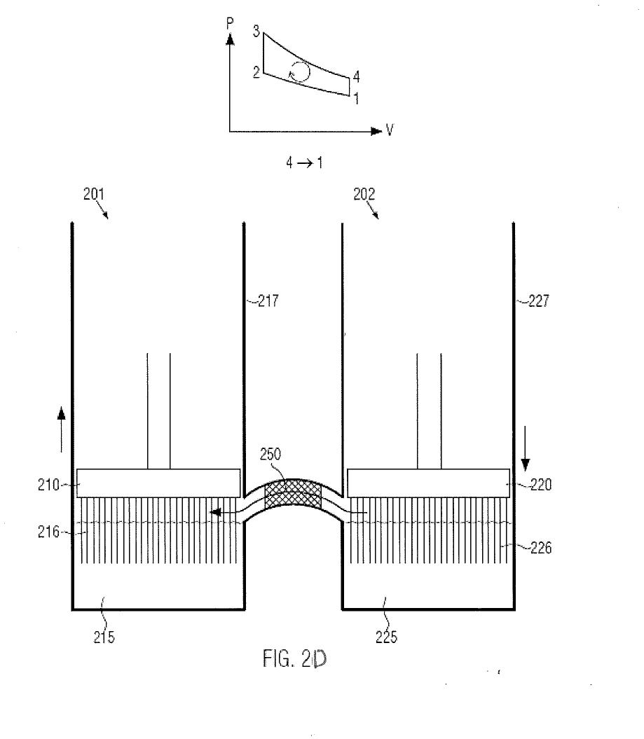

FIGS. 2 A-D show a possible realization of a thermodynamic cycle with the thermoelectric converter according to the disclosure in the sense of a clockwise cycle. As is well-known, in thermodynamics clockwise cycles realize thermal engines which convert supplied heat into work. In FIG. 2 a-d, the corresponding pV diagram of a clockwise cycle consisting of two isothermal and two isochoric changes of states is always represented. The following illustrations assume in a simplified manner that the process control is ideal, that means that the changes of state of the gas are infinitesimal and the process gas can be described as an ideal gas during each change of state, and furthermore the changes of state correspond to ideal isotherms and isochores. The cylinders 201 and 202 represented in FIGS. 2a-d are shown in a very simplified manner for a better overview. For completely realizing the described process, they would have to comprise, for example, at least further or all components of the cylinders of FIG. 1.

FIG. 2A describes the operations in the cylinders 201 and 202 during the change of state of state 1 described by the temperature T₀, the pressure p₁ and the volume V₁, to state 2 described by the temperature T₀, the pressure p₂, and the volume V₂. This change of state is an isothermal compression in which the volume of the process gas is decreased and the pressure of the gas is increased at a constant temperature (change of internal energy dU=0). For this, the piston 220 in the cylinder 202 is at rest, preferably in a position in which no gas can flow out of the cylinder 201 via the connecting element 250 into the cylinder 202. Simultaneously, the piston 210 in the first cylinder 201 is moved in a direction towards the liquid volume and the liquid 215. For the temperature to remain constant, it is provided that the liquid, and in particular the heat transfer elements 216, have a lower temperature than the process gas. In this way, the process gas can emit heat to the heat transfer elements 216 during compression. As soon as the heat transfer elements 216 are in communication with the liquid in the liquid volume 215, this heat is emitted to the liquid which emits the supplied heat to the heat reservoir via the thermal coupling with the external heat reservoir. For compressing the gases during the isothermal compression from state 1 to state 2, work ΔW is performed at the gas by the piston 210 or by the preferably electromagnetic components moving this piston 210, and optionally additionally by the pressure of the gas volume 260 located above the piston 210. If this process is running sufficiently slowly, a complete heat exchange of the gas with the heat transfer elements 216 and the liquid 215 can be realized, so that a complete conversion of the work ΔW performed at the gas into heat ΔQ is possible. At the end of the change of state, the gas has reached state 2 in which it is described by the temperature T₀, the pressure p₂ and the volume V₂.

FIG. 2B shows the change of state from state 2 to state 3 described by the temperature T₁, the pressure p₃, and the volume V₂, the change of state being an isochoric heating. In the process, the piston 220 in the cylinder 202 is moved upwards exactly to the extent to which the piston 210 is moved downwards in the cylinder 201. Thereby, gas flows out of the cylinder 201 through the connecting element 250 with the regenerator into the cylinder 202. The liquid in the cylinder 202 in the liquid volume 225 has a higher temperature T₁. The contact of the process gas with the heat transfer elements 226 and the liquid 225 at its surface lead, in particular due to the large surface area of the heat transfer elements 226, to the process gas being heated from its temperature T₀ to the temperature T₁ by heat absorption at a sufficiently slow process control (movement of the pistons 210 and 220). Since the available gas volume in the cylinder 202 increases by the upward movement of the piston 220 exactly to the same extent as the gas volume available in the cylinder 201 decreases by the downward movement of the piston 210, the volume available for the gas does not change, and therefore no work is performed. At the end of this change of state, the piston 210 in the cylinder 201 is in a position in which preferably all the gas is displaced from the cylinder 201, the heat transfer elements 216 are nearly completely immersed in the liquid volume 215 for heat exchange with the liquid 215, and possibly the connection 250 has been closed, so that no gas can flow back. The gas is then described by the temperature T₁, the pressure p₃, and the volume V₂. During the passage of the gas from the cylinder 201 into the cylinder 202, it has passed the regenerator in the connecting element 250 and absorbed the heat stored in this regenerator from the previous cycle. Simultaneously, due to the large surface of the heat transfer elements 226, a lot of heat has been transferred to the gas during its passage into the cylinder 202.

FIG. 2C shows a change of state from state 3 to state 4, described by the temperature T₁, the pressure p₄, and the volume V₄, the change of state being an isothermal expansion. Since the gas still absorbs heat from the heat transfer elements 226 and the surface of the liquid in the liquid volume 225, but the piston is simultaneously not fixed (to this end, the coils that are responsible for the movement by electromagnetic forces are preferably switched such that they convert the work performed by the gas at the piston 220 into electric energy), the gas performs work by lifting the piston 220. If this process is running sufficiently slowly, the gas will perform exactly as much work at the piston 210 as it absorbs heat from the heat transfer elements 226 and the liquid in the liquid volume 225. Due to the large surface area of the heat transfer elements 226, the process can in reality still run at high speed compared to common devices, and simultaneously, a preferably ideal isothermal change of state can be achieved because the heat exchange between the gas and the heat transfer element 226 is very effective. By lifting the piston, the gas performs work at the piston 220 at the temperature T₁ and thus performs volume work.

FIG. 2D shows the change of state from state 4 to state 1 which is isochoric cooling. In the process, the piston 210 is moved upwards again in the cylinder 201, whereby gas flows from the piston 202 into the cylinder 201 via the connection 250 with the regenerator. Simultaneously, the piston 220 is moved downwards in the cylinder 202. During its passage from the cylinder 202 into the cylinder 201, the gas emits heat to the regenerator in the connecting element 250 and thereby reduces its temperature. It furthermore emits heat to the heat transfer elements 216 and the surface of the liquid in the liquid volume 215 in the cylinder 201, whereby it cools down further. Thereby, the pressure on the pistons 210 and 220 decreases because the volume is held constant, and thereby the emission of heat to the heat transfer elements 216 and the liquid in the liquid volume 215 and the regenerator in the connecting element 250 results in a change of the internal energy of the gas. The gas has thus reached again its original state 1, characterized by the temperature T₀, the pressure p₁, and the volume V₁. The heat transfer elements 216 and 226 permit a very effective exchange of heat due to their very large surfaces both with the liquid in the liquid volumes 215 and 225 and with the process gas. Thereby, a process control can be achieved which is, in its actual implementation, essentially closer to the ideal isochoric and isothermal changes of state than with common devices without heat transfer elements or without liquid, and thus a considerably higher efficiency can be achieved.

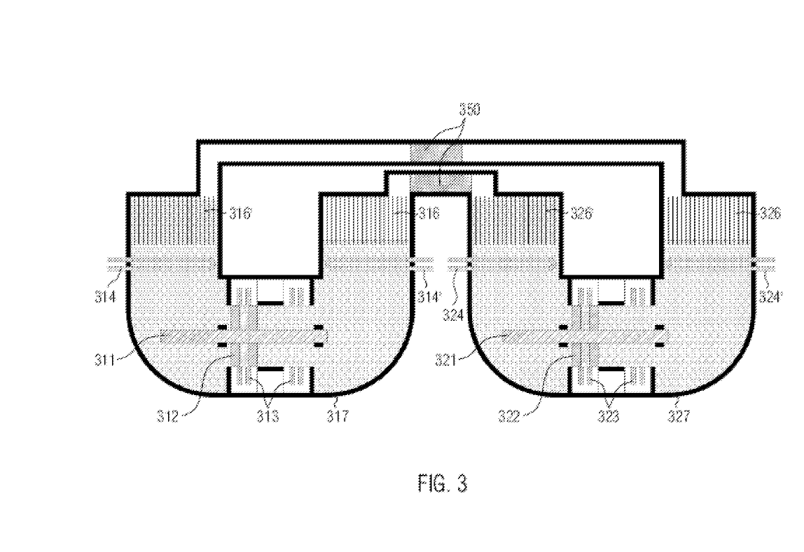

FIG. 3 shows an embodiment according to the disclosure in which no solid volume-changing element for changing the gas volume is provided, but the change of the available gas volumes is caused by changing the liquid level. Simultaneously, the heat transfer elements 316, 316′ and 326 and 326′ are arranged such that they immerse in the liquid to different degrees when the liquid level is changed. In this embodiment, two connecting elements 350 with one regenerator each are provided. Furthermore, in the primary volumes 317 and 327, two separate regions are provided which are thermally coupled to heat reservoirs, sources or sinks via individual heat exchangers 314, 314′ and 324 and 324′. In each of the primary volumes 317 and 327, moreover the already known arrangement for changing the volume from FIG. 1 is provided. To begin with, the latter comprises a piston rod 311 or 321 which prevents, via hydrodynamic bearings, a shifting of the permanent magnet 312 and 322 beyond a certain maximum due to magnetic forces between permanent magnets and ferromagnetic components, that are arranged around the coils 313 and 323. The permanent magnet 312 and 322 is disposed between the coils 313 and 323 such that no or only very little liquid exchange takes place between the individual regions of each primary volume 317 and 327. This ensures that in the given shape of the primary volumes 317 and 327 according to a U-shape, different liquid levels can be achieved independent of the pressures of the gases located above them and resulting due to the different states according to FIG. 2. If the permanent magnet 312 or 322 is moved by the coils 313 or 323, respectively, the level of the liquids changes, and thus work can be performed either by the process gas or at the process gas by changing the available volume. Here, a complete cycle each runs via the parts of the primary volumes 317 and 327 connected to one of the connecting elements 350. Consequently, for example the changes of state that are taking place are each offset by 180°. This means for example that, if one of the process gases is isothermally compressed, the other process gas will undergo isothermal expansion. The same applies to the isochoric changes of state.

FIG. 4 shows a device according to the disclosure in an embodiment according to a duplex-alpha Stirling machine. Here, four cylinders 470, 471, 472 and 473 are provided. Each of these cylinders comprises all elements that are also provided in the cylinders 101 and 102 in FIG. 1. Moreover, two cylinders are connected with connecting elements 450, and two cylinders are connected with openings 460. Here, the connection is provided such that the cylinders which are connected to each other via connecting elements 450 are not connected via connecting elements 460, and the cylinders that are connected via connecting elements 460 are not connected to each other via connecting elements 450. According to FIG. 3, the cylinders 470 and 471 are consequently connected to each other via connecting elements 450 with a regenerator, just as the cylinders 472 and 473. The cylinders 470 and 473 and 471 and 472, respectively, are not connected to each other via such connecting elements 450, but via connecting elements 460 without regenerator. The connecting elements 450 with the regenerator take over the same task as described in FIG. 1 and in FIG. 2a-d. The connecting elements 460 are permeable to gas and ensure the required pressure compensation. If the device is in operation, the phase shift of the processes running in the cylinders 470 and 471 is about 180° to the processes running in the cylinders 472 and 473. This means that, if the process gas of the cylinders 470 and 471 is in isothermal compression, the process gas of the cylinders 472 and 473 is in isothermal expansion. This arrangement can be used for either utilizing the temperature difference between two heat reservoirs that adjoin said arrangement outside to achieve a corresponding temperature difference in the two other heat reservoirs, or for converting the temperature differences of the heat reservoirs given from outside into electric energy, or for utilizing electric energy for generating temperature differences in the adjoining heat reservoirs. Preferably, the heat reservoirs 414 in the first and in the last alternatives comprise liquid flows into which temperature differences are transferred in this way, or in which temperature differences are generated in this way. To change the quantities or ratios of the quantities of heat or electric energy utilized for driving the device and of the generated quantities of heat and electric energy, the phase shift of the processes running in the cylinders can be adjusted to deviate from 180°, and/or the movement of the pistons relative to each other represented in FIG. 2 can be phase shifted.

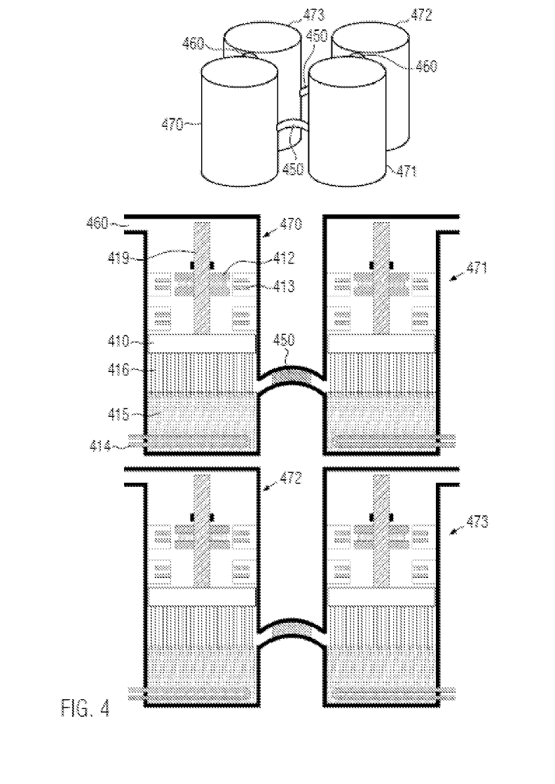

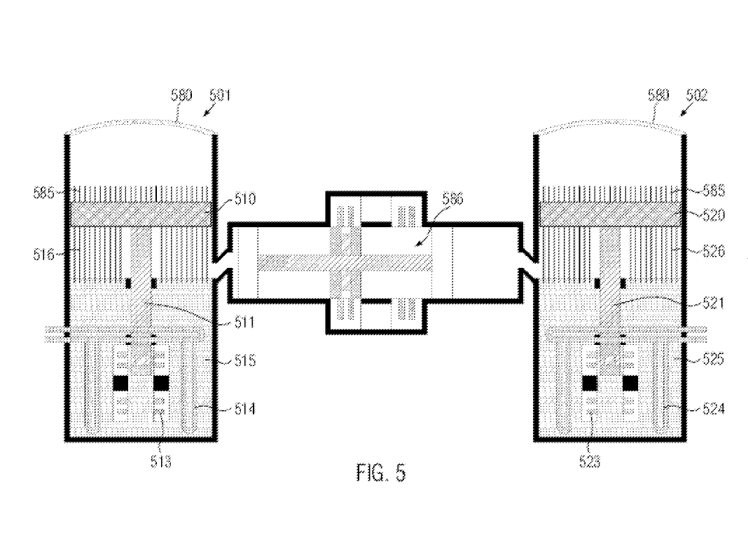

FIG. 5 shows a device according to the disclosure in an embodiment as a duplex-gamma Stirling machine, where here the volume-changing elements 510 and 520 simultaneously take over the function of the regenerators. The volume-changing elements 510 and 520 are therefore designed here to be permeable to gas and they change both the size of the primary volumes disposed above them and the size of the primary volumes disposed underneath them. In this embodiment, only those primary volumes that are underneath the volume changing elements contain a liquid volume. Above the volume-changing elements 510 and 520, absorbers 585 for absorbing electromagnetic radiation are installed. Underneath the volume-changing elements 510 and 520, heat transfer elements 516 and 526, respectively, are provided in the direction of the liquid volume 515 and 525. The device for moving the volume-changing elements 510 and 520, which comprises the piston rod 511 and 521 and the coils 513 and 523, respectively, and the permanent magnets 512 and 522, is preferably accommodated in the liquid volume 515 and 525 together with the heat exchangers or lines 514 and 524 to external heat reservoirs, sources or sinks. Furthermore, the lid 580 of each cylinder 501 and 502 is permeable to a wavelength range of electromagnetic radiation, preferably for the total spectral region of sunlight. Moreover, a double-acting working piston 586 is provided as a connection between the cylinders 501 and 502. The absorber 585 emits the absorbed energy of incident electromagnetic radiation to the process gas coming from the regenerator 510 and 520, flowing around it and heating it thereby. After the gas has flown back through the regenerators 510 and 520, it can emit heat to the heat transfer elements 516 and 526 which in turn emit this heat by their movement into the liquid volume with the liquids 515 and 525 by heat exchange. The heat absorbed by the liquid is then transferred to the heat reservoirs via further transmission through the heat exchangers 514 and 524. Since by the heating and cooling of at least a portion of the process gas in the cylinders 501 and 502 pressure variations can occur, the double-acting working piston 586 is provided which can convert the volume work of the process gas resulting from the pressure variations into electric energy. For this, it is preferably provided in a separate cylinder. For converting the performed volume work into electric energy, this cylinder can comprise several coils and one or several permanent magnets at the working piston. However, a transmission of the volume work by the working piston 586 can be suitably also achieved with the aid of direct mechanical connections, e.g. with an axle. FIG. 5 shows a sectional drawing which can be realized e.g. in a structural shape with a circular base of the primary volumes, or in another structural shape, e.g. with a rectangular cross-section. The latter could be directly arranged under an oblong Fresnel lens or in a parabolic trough reflector.

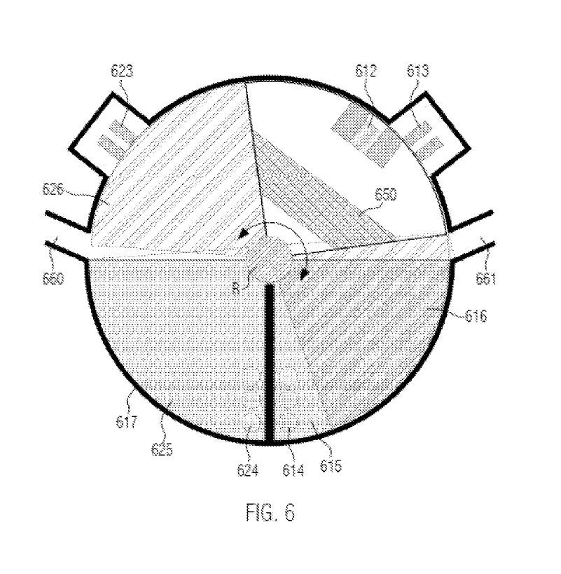

FIG. 6 shows a device according to the disclosure using a rotary piston that can rotate about an axis of rotation R. Its rotation is preferably also achieved via electromagnetic components, in particular a permanent magnet 612 and coils 613 and 623. The rotary piston is divided into four segments. In one segment, the permanent magnet 612 and a regenerator 650 are preferably located, this segment being designed to be permeable to gas at least in the region of the regenerator. In the two segments 616 and 626 adjoining this segment, the heat transfer elements are located which are here realized as metallic plates arranged in parallel with respect to each other and orthogonally to the axis of rotation. The fourth segment does not have any further solid components. The rotary piston is located in a container 617 having a circular cross-section. As a three-dimensionally extended body, the latter can preferably be a cylinder. In addition, gas supply lines 660 and 661 are provided. Furthermore, the axis of rotation R of the rotary piston is positioned such that it extends through the cylinder concentrically and simultaneously lies in the plane forming the liquid level of the liquids 615 and 625. In the liquid volumes 615 and 625, heat exchangers or lines 614 and 624 for thermally coupling the liquid in the liquid volumes 615 and 625 to the external heat reservoirs, sources or sinks are furthermore provided. The limitations of the individual segments preferably start orthogonally from the axis of rotation.

By oscillating rotation of the rotary cylinder about the axis of rotation R, one thus achieves that the heat transfer elements 616 and 626 alternatively immerse into the liquid volumes 615 and 625, and the gas transported through the supply 660 and 661 is simultaneously moved between the segments with the heat transfer elements 616 and 626 and the segment with the regenerator 650, and in this manner, a corresponding cycle can be realized by heat transfer.

If the represented device is intended to be used in connection with a gamma Stirling machine, one of the openings 660 or 661 is closed and the other opening leads to a working piston which is also in particular present as a rotary piston, or in another one of the described embodiments, or in another realization as working piston. As an alternative, it is also possible to connect the arrangement with a further arrangement of the same structure and to thus realize a Vuilleumier cycle machine. It is furthermore conceivable to realize a duplex Stirling machine by connection with a double-acting working piston, as described in FIG. 5, and two devices with rotary piston. It is furthermore conceivable to realize the rotary piston without regenerator, i.e. it is not permeable to gas, and to thus realize a duplex-alpha Stirling machine with two such rotary pistons.

It is an advantage that all described embodiments according to the disclosure except for the one represented in FIG. 5 are suited both for the realization of a clockwise and an anticlockwise thermodynamic cycle. Thus, just by a few structural changes, the machine can be used both as thermal engine (for converting quantities of heat into electric energy) and as heat pump (for converting electric energy into quantities of heat). Furthermore, each of the embodiments, except for the one described in FIG. 5, can be used under very high pressure. To avoid gas losses via the containers limiting the process gas volumes (e.g. by diffusion), the containers or primary volumes can be surrounded by an additional pressure tank which is filled with gas under an equally high pressure which less easily diffuses or exits through this outer pressure tank. Thus, no high pressure differential occurs any longer beyond the limits of the primary volumes, and the diffusion of the process gas out of the primary volume is thus clearly restricted.

1. A thermoelectric converter for converting quantities of heat into electric energy, or electric energy into quantities of heat, or quantities of heat of certain temperatures into quantities of heat of certain other temperatures, comprising:
at least two primary volumes connected to each other by at least one connecting element, the primary volumes each comprising one gas volume that is suited for receiving gas, and
wherein at least one of the primary volumes comprises a liquid volume suited for receiving a liquid,
wherein the liquid can be thermally coupled to an external heat reservoir or an external source of heat or an external heat sink, and
wherein at least one volume-changing element is provided in at least one of the primary volumes for changing the size of the gas volume, and wherein
a heat transfer element is provided in at least one of the primary volumes, the proportion of the heat transfer element located in the liquid volume being variable.

2. The thermoelectric converter of claim 1, wherein the heat transfer element comprises a surface area that is larger than the surface area of surfaces defining the gas volume.

3. The thermoelectric converter of claim 1, wherein the heat transfer element is fixed to the surface of the volume-changing element facing the liquid volume.

4. The thermoelectric converter of claim 1, wherein the heat transfer element comprises:
a plurality of separate plates consisting of a material that is a good heat conductor;
a plurality of separate rods, consisting of a material that is a good heat conductor;
a metallic foam permeable to liquids and gases;
a plurality of grids connected to each other, consisting of a material that is a good heat conductor;
an arrangement of a material that is a good heat conductor with spaces whose dimensions into at least one direction are <20 mm, preferably <10 mm, preferably <2 mm.

5. The thermoelectric converter of claim 1, wherein electromagnetic components are provided that are suited for a movement of the volume-changing element.

6. The thermoelectric converter of claim 1, wherein the volume-changing element is one of:
a shifting piston, and
a rotary piston.

7. The thermoelectric converter of claim 1, wherein at least at one volume-changing element or at the surfaces defining the primary volume, a movable absorber is provided which can convert electromagnetic radiation into heat and transmit it to the process gas.

8. The thermoelectric converter of claim 1, wherein the device is one of:
an alpha Stirling machine,
a duplex-alpha Stirling machine,
a multiple-acting alpha Stirling machine,
a gamma or beta Stirling machine,
a duplex-gamma or duplex-beta Stirling machine,
a multiple-acting gamma or beta Stirling machine, and
a Vuilleumier cycle machine.

9. A method for converting quantities of heat into electric energy, or electric energy into quantities of heat, or quantities of heat of certain temperatures into quantities of heat of certain other temperatures, by means of a thermoelectric converter comprising at least two primary volumes connected to each other by at least one connecting element, each primary volume comprising a gas volume with a process gas, and wherein at least one of the primary volumes comprises a liquid volume with a liquid, the liquid being thermally coupled to an external heat reservoir or an external source of heat or an external heat sink, and wherein at least one volume-changing element causes a change of the size of the gas volume in at least one of the primary volumes, the method comprising:
periodically changing the proportion of a heat transfer element located in the liquid volume.

10. The method of claim 9, wherein liquid is permanently present in the liquid volume.

11. The method of claim 9, further comprising:
periodically moving or deforming the volume-changing element by electromagnetic components, wherein the movement or deformation of the volume-changing element is controlled by the electromagnetic components by open-loop or closed-loop control.

12. The method of claim 9, further comprising:
controlling the amplitude of the movement of the volume-changing element such that the speed of the volume-changing element, when it passes the center of motion, is higher than the speed of a harmonic oscillation of the same period.

13. The method of claim 9, further comprising:
moving the volume-changing elements in the primary volumes such that during a compression phase, a multiple of the process gas of the first primary volume is located in the second primary volume, and during an expansion phase, a fraction of the process gas of the first primary volume is located in the second primary volume.

14. The method of claim 9, further comprising: the change of the size of the gas volume is accomplished by changing the proportion of the liquid volume in the primary volume.

15. The thermoelectric converter of claim 1, wherein both of the primary volumes comprise a liquid volume suited for receiving a liquid.

16. The device of claim 1, wherein the heat transfer element is firmly provided at the surfaces defining the primary volume.

17. The thermoelectric converter of claim 4, wherein the plates are made of metal, the separate rods are made of metal, and the grids are made of metal.

18. The thermoelectric converter of claim 1, wherein the volume-changing element is a movable membrane.

19. The thermoelectric converter of claim 1, wherein the volume-changing element is a movable regenerator.

20. The thermoelectric converter of claim 1, wherein the volume-changing element is the liquid.
